(19) United States
(12) Patent Application Publication
(10) Pub. No.: US 2007/0253177 A1
(43) Pub. Date: Nov. 1, 2007

(54) Circuit unit, power supply bias circuit, LNB and transistor capable of suppressing oscillation of a board

(75) Inventor: Masayuki Nibe, Osaka (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/783,248

(22) Filed: Apr. 6, 2007

(30) Foreign Application Priority Data
Apr. 27, 2006 (JP) 2006-123832(P)

(51) Int. Cl. H05K 1/18

(52) U.S. Cl. 361/763

(57) ABSTRACT

A bypass capacitor is arranged at an end of a main surface of a circuit board. More specifically, the bypass capacitor is arranged at the end of the main surface of the circuit board such that conductor pattern is located closer to the end of the circuit board than earth pattern. In this position, an earth pattern and a through hole electrode do not surround an outer side of a power supply line. Arrangement of the bypass capacitor in this position can particularly suppress radiation noises that may emerge from a resonance end surface of the board. Therefore, it is possible to provide a circuit unit, a power supply bias circuit, an LNB and a transmitter capable of suppressing oscillation at a certain frequency that cannot be sufficiently suppressed by a conventional bypass capacitor.

This nonprovisional application is based on Japanese Patent Application No. 2006-123832 filed with the Japan Patent Office on Apr. 27, 2006, the entire contents of which are hereby incorporated by reference.

### BACKGROUND OF THE INVENTION

1. Field of the Invention

The present invention relates to a circuit unit, a power supply bias circuit, an LNB (Low Noise Block down-converter) and a transmitter that can be used in transmit-receive devices for satellite broadcasting, satellite communications and fixed radio.

2. Description of the Background Art

An LNB (Low Noise Block down converter) and a transmitter are attached to an antenna that is called an “outdoor unit” in a bidirectional satellite broadcasting transmit-receive system. The LNB receives RF (Radio Frequency) signals, i.e., extremely weak radio waves from a satellite via an antenna, performs low-noise amplification on the received RF signals and performs frequency conversion to provide IFs (Intermediate Frequencies). The LNB provides the low-noise IF signals at a sufficient level to an indoor unit. The transmitter performs frequency conversion on the signal received from the indoor unit to produce an RF signal, and amplifies it. The transmitter transmits the amplified RF signal to a satellite via an antenna.

In the above bidirectional satellite transmit-receive system, a user can get service of the bidirectional communications such as satellite broadcasting and the Internet connection service, using a terminal such as a television set or a computer connected to the indoor unit.

In the LNB and the transmitter, an amplifier circuit, a mixer, a local oscillator circuit and the like are referred to as active circuits, and can be driven by supplying an appropriate electric power to semiconductor elements. The semiconductor element is supplied with the power from a power supply circuit via a bias circuit. The bias circuit is formed of a lumped constant circuit such as a chip resistance, a chip capacitor, a chip inductor or the like, and a distributed constant circuit formed of a conductor pattern.

A bias circuit must be designed to attain an open state in a frequency band of a signal that is processed by a semiconductor element driven by the bias circuit. When viewed from the semiconductor element, the bias circuit in the open state is equivalent to a structure in which the bias circuit is not present in the frequency band in question. Therefore, it is possible to suppress loss of the signal as well as unnecessary oscillation due to return of the signal from an output side of the semiconductor element to its input side via the bias circuit.

For interrupting the radio-frequency signal to the bias circuit, a bypass capacitor may be connected between an interconnection pattern and an earth pattern.

FIG. 11 illustrates a bypass capacitor arranged on a circuit board.

Referring to FIG. 11, a conductor pattern 151 and an earth pattern 152 are formed on one of surfaces of a dielectric board, i.e., a circuit board 150. A ground layer 154 is formed on the other surface of circuit board 150. Earth pattern 152 is connected to ground layer 154 via a through hole electrode 153 extending through a dielectric layer 150A of circuit board 150. A bypass capacitor C1 is connected between conductor pattern 151 and earth pattern 152. Bypass capacitor C1 is, e.g., a chip capacitor.

The capacitor has a property of passing an AC without passing a DC. As shown in FIG. 11, a radiation signal S1 provided from a signal source 155 flows through bypass capacitor C1. Radiation signal S1 that passed through bypass capacitor C1 flows through earth pattern 152 and through hole electrode 153 into a ground layer 154. Thereby, unnecessary signals can escape to ground layer 154. Radiation signal S1 returns from ground layer 154 via through hole electrode 153 to signal source 155.

As shown in FIG. 11, bypass capacitor C1 is basically arranged as close to signal source 155 as possible for the purpose of rapidly returning unnecessary signals to the signal source. It is also intended to prevent such a problem that conductor pattern 151 and ground layer 154 operate as an antenna to radiate noises into the space.

As an example of a radio-frequency circuit using a bypass capacitor, Japanese Patent Laying-Open No. 2000-349443 has disclosed a multilayer printed board that can suppress occurrence of unnecessary radiation. This multilayer printed board includes a first connection arranged at a signal interconnection layer for electrically connecting a bypass capacitor between a power supply layer and a ground layer, and a second connection neighboring to the first connection and arranged at the signal interconnection layer for electrically coupling the bypass capacitor via an inductance element between the power supply layer and the ground layer. Since this multilayer printed board is configured to connect the bypass capacitor selectively to the first and second connections, a resonance frequency of a harmonic component caused by an implemented IC or the like can be readily changed, and occurrence of unnecessary radiation can be suppressed.

For example, Japanese Patent Laying-Open No. 2001-024334 has disclosed, as another example, a multilayer printed board that can reduce occurrence of radiation noises. This multilayer printed board has a power supply layer, a ground layer and a signal layer that are stacked with insulating layers therebetween, and has various kinds of integrated circuit elements at a surface layer. Bypass capacitors are arranged between the power supply layer and the ground layer of this multilayer printed board. The bypass capacitors are arranged at respective “equally divided regions” prepared by equally dividing a region where the power supply layer and the ground layer are opposed to each other into regions of the same form and area. This multilayer printed board employs a smaller number of bypass capacitors, and can shift a peak frequency of the radiation noises of the power supply system due to resonance to a higher side.

For example, Japanese Patent Laying-Open No. 08-204472 has disclosed, as still another example, a radio-frequency amplifier circuit that allows easy designing of devices such as a MCIC (MultiChip IC) and a MMIC (Microwave Monolithic IC). This radio-frequency amplifier circuit includes a parallel resonance circuit that is formed of a dielectric element and a capacitive element and is arranged between a drain terminal and a drain power supply of an FET (Field Effect Transistor) element, and also includes a parallel resonance circuit having a similar structure and arranged between a gate terminal and a gate power supply. This radio-frequency amplifier circuit can achieve a high impedance and a constant impedance in a bias circuit without using large circuit elements.

For example, Japanese Patent Laying-Open No. 09-289421 has disclosed, as yet another example, a radio-frequency power amplifier using a field-effect transistor. In this radio-frequency power amplifier, a drain bias circuit of the field-effect transistor employs a parallel resistance circuit formed of a microstrip line and a capacitor. This can reduce sizes of the radio-frequency power amplifier.

The LNB or the transmitter generally employs a high dielectric capacitor having a capacitance value of 1000 pF or more as a bypass capacitor.

FIG. 12 illustrates impedance-frequency characteristics of capacitors.

FIG. 12 illustrates changes in impedance with respect to the frequency of capacitors having capacitance values of 1 pF, 10 pF, 100 pF and 1000 pF. A frequency of a value minimizing the impedance is a self-resonance frequency of a capacitor.

The capacitor becomes dielectric at the self-resonance frequency, and becomes capacitive at other frequency values. On the frequency side lower than the self-resonance frequency, the impedance value increases with decrease in frequency. On the frequency side higher than the self-resonance frequency, the impedance value increases with increase in frequency.

The high-dielectric capacitor having a capacitance value of 1000 pF or more has a self-resonance frequency lower than 150 MHz, and effectively functions as a bypass capacitor in a radio-frequency circuit processing signals of 1 GHz or higher.

However, unnecessary radiation occurs not only form the conductor pattern but also from an end surface of the circuit board.

FIG. 13 illustrates the radiation from the end surface of the circuit board.

Referring to FIG. 13, a radiation noise does not occur in a region between earth pattern 152 and ground layer 154 in circuit board 150. When the frequency of the signal provided from signal source 155 on the circuit board is close to the resonance frequency of an LC resonance circuit formed of a parasitic capacitance, a parasitic inductance or the like between the interconnections, radiation signals S2A and S3A radiate from end surfaces 150B and 150C into the space. Radiation signals S2A and S3A return into the board or another semiconductor element via various paths, and cause noises or unnecessary oscillation. When the signal generated by signal source 155 has a frequency different from the resonance frequency of the board itself, radiation signals S2B and S3B are reflected by the end surfaces of the board, and remain in dielectric layer 150A.

FIG. 14 illustrates a manner of preventing the radiation from the end surface of the circuit board.

Referring to FIG. 14, through hole electrodes 153 arranged at the ends of circuit board 150 connect earth pattern 152 to ground layer 154. Although not shown in FIG. 14, earth pattern 152 located at the surface of circuit board 150 surrounds the periphery of circuit board 150. This structure can prevent the radiation at end surfaces 150B and 150C of the board. Radiation signals S2C and S3C are reflected by end surfaces 150B and 150C of the board, and remain in the board. As described above, the earth pattern surrounds the periphery of the circuit board, and the through hole electrodes connect the earth pattern to the ground layer. This configuration has been employed for preventing the radiation from the end surface of the board.

In some cases, however, it may be difficult to arrange the through holes at the peripheral portion of the board due to restrictions in board layout. In these cases, unnecessary radiation can be dealt with by arranging bypass capacitors at various portions of the conductor pattern. However, the magnitude of the effect of suppressing the radiation depends on the positions and the number of the bypass capacitors. Problems such as oscillation occur when the radiation from the board end cannot be fully suppressed by only the bypass capacitors.

### SUMMARY OF THE INVENTION

An object of the invention is to provide a circuit unit, a power supply bias circuit, an LNB and a transmitter capable of suppressing oscillation of a board at a specific frequency that cannot be fully suppressed by ordinary bypass capacitors.

In summary, a circuit unit includes a circuit board having a conductor pattern and an earth pattern on a main surface thereof, and a capacitor connected between the conductor pattern and the earth pattern. A self-resonance frequency of the capacitor is included in a resonance frequency band of electrical oscillation of the circuit board.

Preferably, the capacitor is arranged at an end of the main surface.

More preferably, the capacitor is arranged at the end of the main surface such that the conductor pattern is located closer to the end of the main surface than the earth pattern.

According to another aspect of the invention, a power supply bias circuit includes a circuit board having a conductor pattern and an earth pattern on a main surface thereof, and a first capacitor connected between the conductor pattern and the earth pattern. A self-resonance frequency of the first capacitor is included in a resonance frequency band of electrical oscillation of the circuit board. The power supply bias circuit further includes a supply control circuit performing supply of power according to a DC voltage applied to the conductor pattern.

Preferably, the power supply bias circuit further includes a second capacitor connected between the conductor pattern and the earth pattern. The first capacitor has a smaller capacitance value than the second capacitor.

According to still another aspect of the invention, an LNB includes a power supply bias circuit. The power supply bias circuit includes a circuit board having a conductor pattern and an earth pattern on a main surface thereof, and a capacitor connected between the conductor pattern and the earth pattern. A self-resonance frequency of the capacitor is included in a resonance frequency band of electrical oscillation of the circuit board. The power supply bias circuit further includes a supply control circuit performing supply of power according to a DC voltage applied to the conductor pattern.

According to yet another aspect of the invention, a transmitter includes a power supply bias circuit. The power supply bias circuit includes a circuit board having a conductor pattern and an earth pattern on a main surface thereof, and a capacitor connected between the conductor pattern and the earth pattern. A self-resonance frequency of the capacitor is included in a resonance frequency band of electrical oscillation of the circuit board. The power supply bias circuit further includes a supply control circuit performing supply of power according to a DC voltage applied to the conductor pattern.

Accordingly, a major advantage of the invention is that the oscillation of the circuit board at a specific frequency can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a structure of a bidirectional satellite transmit-receive system provided with a circuit unit, a power supply bias circuit, an LNB and a transmitter according to an embodiment of the invention.

FIG. 2 is a functional block diagram of an LNB 5 in FIG. 1.

FIG. 3 schematically shows an arrangement of bypass capacitors C1 and C2 on a circuit board shown in FIG. 2.

FIG. 4 shows more specifically an arrangement of bypass capacitor C2 on the circuit board.

FIG. 5 illustrates characteristics of an output return loss that occurs at an output terminal 40 when LNB 5 in FIG. 2 is provided with only bypass capacitor C1 between bypass capacitors C1 and C2.

FIG. 6 illustrates characteristics of the output return loss that occurs at an output terminal 40 when the LNB in FIG. 2 includes bypass capacitors C1 and C2.

FIG. 7 illustrates changes in signal waveform caused by addition of bypass capacitor C2 in the LNB shown in FIG. 2.

FIG. 8 is a functional block diagram of a transmitter 9 shown in FIG. 1.

FIG. 9 illustrates a model of a board used for calculating a resonance frequency.

FIG. 10 illustrates, in a table form, the resonance frequency of the board calculated according to an approximation.

FIG. 11 illustrates a bypass capacitor arranged on a circuit board.

FIG. 12 illustrates frequency characteristics of an impedance of a capacitor.

FIG. 13 illustrates radiation from an end surface of a circuit board.

FIG. 14 illustrates a manner of preventing radiation from an end surface of a circuit board.

### DESCRIPTION OF THE PREFERRED EMBODIMENTS

Embodiments of the invention will now be described with reference to the drawings. In the following drawings, the same or corresponding portions bear the same reference numbers.

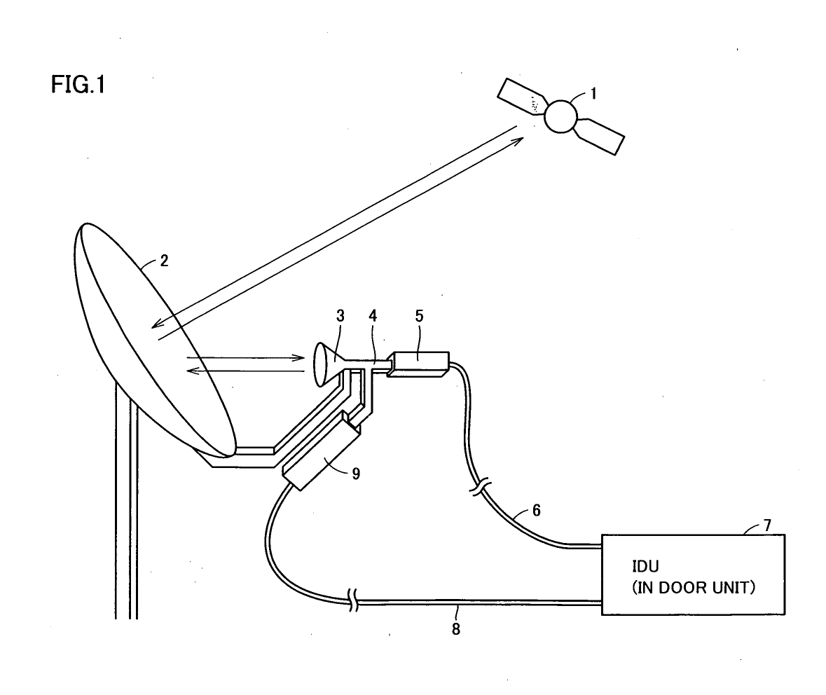

FIG. 1 shows a structure of a bidirectional satellite transmit-receive system provided with a circuit unit, a power supply bias circuit, an LNB and a transmitter according to an embodiment.

Referring to FIG. 1, the bidirectional satellite transmit-receive system includes a bidirectional satellite 1, a parabolic antenna 2, a feed horn 3, an OMT (Orthogonal Mode Transfer) 4, an LNB (Low Noise Block down converter) 5, a reception coaxial cable 6, an indoor unit 7, a transmission coaxial cable 8 and a transmitter 9.

Parabolic antenna 2 converges an RF signal transmitted from bidirectional satellite 1. Parabolic antenna 2 is referred to as an “outdoor unit” with respect to indoor unit 7. Feed horn 3 further converges the RF signal converged by parabolic antenna 2, and transmits it to OMT 4. OMT 4 demultiplexes the RF signal transmitted from feed horn 3 according to a direction of cross polarization. LNB 5 converts the RF signal transmitted from feed horn 3 via OMT 4 into a low-noise IF (Intermediate Frequency) signal at a sufficient level. The signal provided from LNB 5 is transmitted via reception coaxial cable 6 to indoor unit (IDU) 7.

The signal provided from indoor unit 7 is transmitted via transmission coaxial cable 8 to transmitter 9. Transmitter 9 converts an IF signal transmitted via transmission coaxial cable 8 into an RF signal at a sufficient level. The RF signal provided from transmitter 9 is transmitted toward bidirectional satellite 1 via OMT 4, feed horn 3 and parabolic antenna 2.

In this bidirectional satellite transmit-receive system, a user can use a terminal such as a television set or a computer (not shown) connected to indoor unit 7, and thereby can receive bidirectional communications service such as satellite broadcasting and Internet connection service.

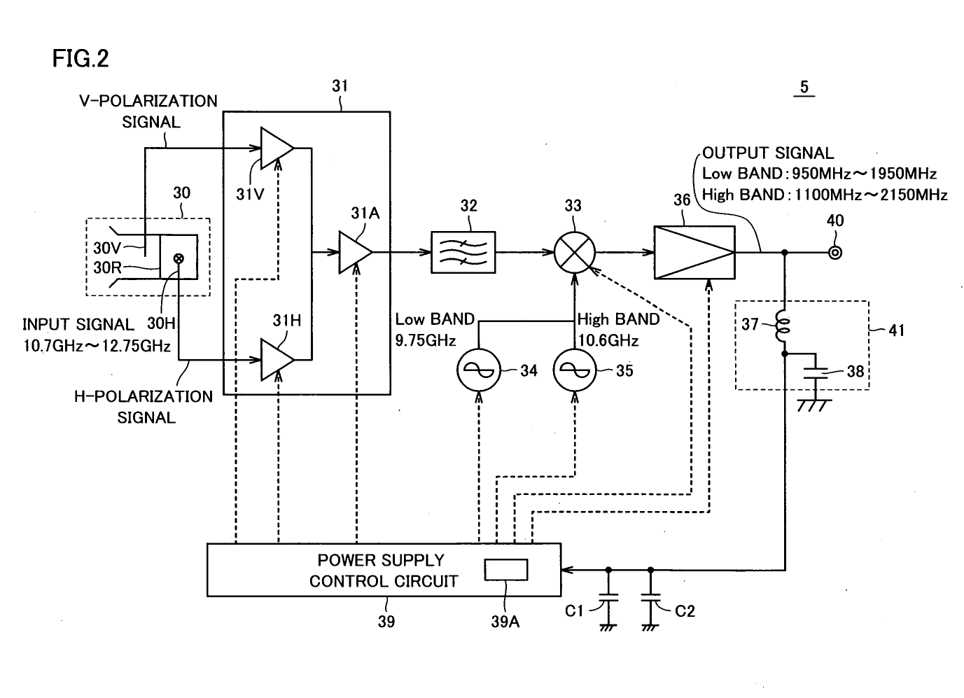

FIG. 2 is a functional block diagram illustrating LNB 5 in FIG. 1.

Referring to FIG. 2, LNB 5 has a two-input and one-output structure, and includes an input waveguide 30, an LNA (Low Noise Amplifier) 31, a BPF (Band Pass Filter) 32, a mixer 33, DROs 34 and 35, an IF amplifier 36, a power supply control circuit 39, an LPF (Low Pass Filter) 41 and bypass capacitors C1 and C2.

LNA 31 includes HEMTs (High Electron Mobility Transistors) 31V, 31H and 31A. An LPF 41 includes an inductor 37 and a capacitor 38.

A V-polarization reflection rod 30R divides an input signal of a frequency of 10.7 GHz-12.75 GHz provided to input waveguide 30 into V- and H-polarization signals. An antenna probe 30V in input waveguide 30 receives the V-polarization signal, and transmits it to HEMT 31V in LNA 31. An antenna probe 30H in input waveguide 30 receives the H-polarization signal, and transmits it to HEMT 31V in LNA 31H.

LNA 31 performs low-noise amplification on one of the V- and H-polarization signals under the control by power supply control circuit 39, and provides it to BPF 32. More specifically, when HEMT 31V in LNA 31 receives the V-polarization signal, HEMT 31V is supplied with the power from power supply control circuit 39, performs the low-noise amplifier on the V-polarization signal and outputs it. When HEMT 31V receives the H-polarization signal, power supply control circuit 39 stops the power supply so that HEMT 31V does not perform the foregoing processing. When HEMT 31H in LNA 31 receives the H-polarization signal, HEMT 31H is supplied with the power from power supply control circuit 39, performs the low-noise amplification on it and outputs it. When HEMT 31H receives the V-polarization signal, power supply control circuit 39 stops the power supply so that HEMT 31H does not perform the foregoing processing.

BPF 32 passes only a desired frequency band in the input signal therethrough, and removes a signal in an image frequency band. The signal passed through BPF 32 is provided to mixer 33.

DRO 34 produces an oscillation signal of a frequency of 9.75 GHz for a Low band, and provides it to mixer 33. DRO 35 produces an oscillation signal of a frequency of 10.6 GHz for a High band, and provides it to mixer 33.

When the Low band signal is received, power supply control circuit 39 supplies the power to DRO 34, and stops the power supply to DRO 35. When the High band signal is received, power supply control circuit 39 supplies the power to DRO 35, and stops the power supply to DRO 34. Thereby, only one of DROs 34 and 35 provides the oscillation signal according to the selection of the Low and High bands.

Mixer 33 receives the oscillation signal from DRO 34 or 35, and performs the frequency conversion to convert the signal received from BPF 32 into an IF signal of a frequency of 950 MHz-1950 MHz when the selection is made to receive the Low band signal. When the selection is made to receive the High band signal, mixer 33 performs the frequency conversion to convert the signal into an IF signal of a frequency of 1100 MHz-2150 MHz.

IF amplifier 36 has appropriate noise characteristics and gain characteristics, and amplifies the IF signal received from mixer 33 for providing it to an output terminal 40.

A receiver i.e., a television set may be connected to output terminal 40 so that it can receive broadcasting programs of the Low and High bands.

Power supply control circuit 39 receives a DC bias and a selection signal via LPF 41. Power supply control circuit 39 selects the V- or H-polarization signal according to the selection signal provided from the receiver, and controls the power supply to HEMTs 31V and 31H as already described. Based on the selection signal provided from the receiver, power supply control circuit 39 selects the Low or High band signal, and controls the power supply to DROs 34 and 35 as already described.

The DC voltage of the selection signal provided from the receiver is 13 V when it represents the V-polarization signal, and is 17 V when it represents the H-polarization signal. The selection signal provided from the receiver is formed of a pulse signal of 22 kHz when it represents the High band signal, and is formed of only a DC component when it represents the Low band signal. Further, power supply control circuit 39 supplies the power to HEMT 31A, mixer 33 and IF amplifier 36. Power supply control circuit 39 corresponds to the “power supply bias circuit” of the invention. Power supply control circuit 39 includes a supply control circuit 39A that supplies the power according to the DC bias supplied from the power supply line.

Since LPF 41 passes only signals of a low frequency band, power supply control circuit 39 does not receive the IF signal provided from IF amplifier 36.

Bypass capacitors C1 and C2 are connected in parallel between the power supply line supplying the DC bias to power supply control circuit 39 and the ground node.

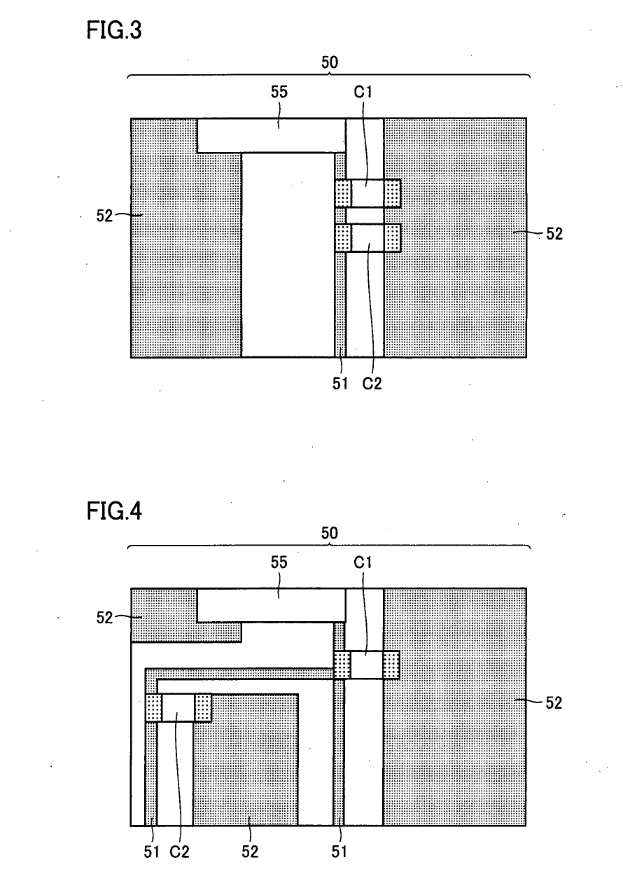

FIG. 3 schematically shows an arrangement of bypass capacitors C1 and C2 on the circuit board in FIG. 2.

Referring to FIG. 3, a circuit board 50 is a dielectric board, and has a conductor pattern 51 and an earth pattern 52 on a main surface thereof. Although not shown in FIG. 3, circuit board 50 is provided at its surface opposite to the main surface with a ground layer, which is connected to earth pattern 52 via a through hole electrode.

Conductor pattern 51 corresponds to a power supply line that supplies the DC bias to power supply control circuit 39 in the circuit diagram of FIG. 2. Earth pattern 52 corresponds to the ground node in the circuit diagram of FIG. 2.

Bypass capacitors C1 and C2 are connected in parallel between conductor pattern 51 and earth pattern 52. Bypass capacitor C2 has a smaller capacitance than bypass capacitor C1. For example, bypass capacitor C2 has a capacitance of about 1.5 pF, and bypass capacitor C1 has a capacitance of about 1000 pF. Circuit board 50 and bypass capacitor C2 form the “circuit unit” of the invention.

As shown in FIG. 3, bypass capacitor C1 is arranged closer to a circuit element 55 than bypass capacitor C2 and, in other words, is located between circuit element 55 and bypass capacitor C2. This arrangement is employed for stabilizing the power voltage supplied to circuit element 55 (for removing low-frequency noises) because the circuit element (power supply control circuit 39) is spaced from the power supply.

Circuit element 55 shown in FIG. 3 is a semiconductor element forming power supply control circuit 39 in FIG. 2. However, the circuit elements may be semiconductor elements or the like forming HEMTs 31V, 31H and 31A as well as IF amplifier 36 in FIG. 2. As described above, bypass capacitor C2 is arranged between the power supply line of the active element of the amplifier circuit and the earth pattern, and this arrangement achieves the effect of suppressing the radiation noises emerging from the end surface of the board due to electrical resonance of the circuit board.

FIG. 4 shows more specifically the arrangement of bypass capacitor C2 on the circuit board.

Referring to FIG. 4, bypass capacitor C2 is arranged at the end of the main surface of circuit board 50. More specifically, bypass capacitor C2 is arranged at the end of the main surface of circuit board 50 such that conductor pattern 51 is located closer to the end of circuit board 50 than earth pattern 52. In this position, the earth pattern and the through hole electrode do not surround an outer side of the power supply line. The arrangement of bypass capacitor C2 in the above position can suppress radiation noises emerging from the resonance end surface of the board.

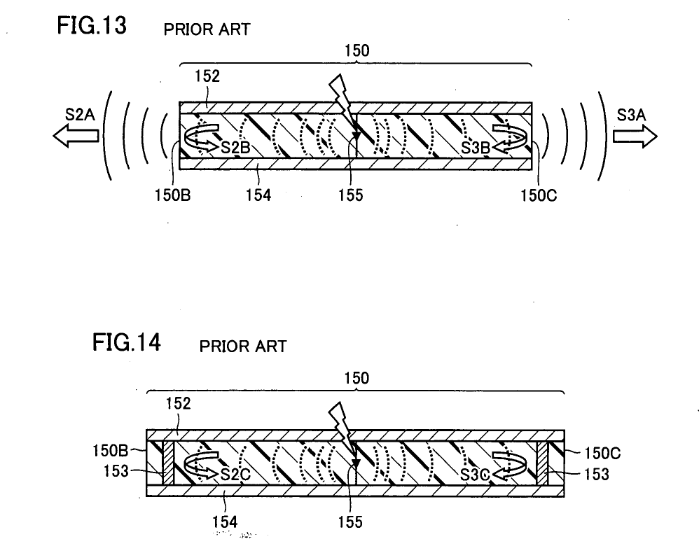

In a conventional structure, as shown in FIG. 13, the earth pattern surrounds the main surface of the board, and the through hole electrode connects the earth pattern to the ground layer so that the radiation from the board end surface can be prevented. However, it is required to minimize sizes of the board bearing the circuit elements for reducing costs, sizes and weights of products. Therefore, when designing the layout of the circuit board, such a situation may occur that the earth pattern cannot surround a periphery of the power supply line. When oscillation occurs near the end of the circuit board having such layout, the power supply line is liable to pick up the noises caused by the resonance.

The self-resonance frequency of bypass capacitor C2 is determined to be included in the resonance frequency band of electrical oscillation of the circuit board. As illustrated in FIG. 12, the capacitor exhibits the lowest impedance at the frequency near the self-resonance frequency. Therefore, when the frequency of the electrical oscillation at the end of the circuit board becomes equal or close to the self-resonance frequency of bypass capacitor C2, a portion connected to bypass capacitor C2 becomes a so-called “low impedance circuit”. Thus, by interposing bypass capacitor C2 at the end of the circuit board, the end of the circuit board is terminated so that the resonance at the end of the circuit board can be suppressed.

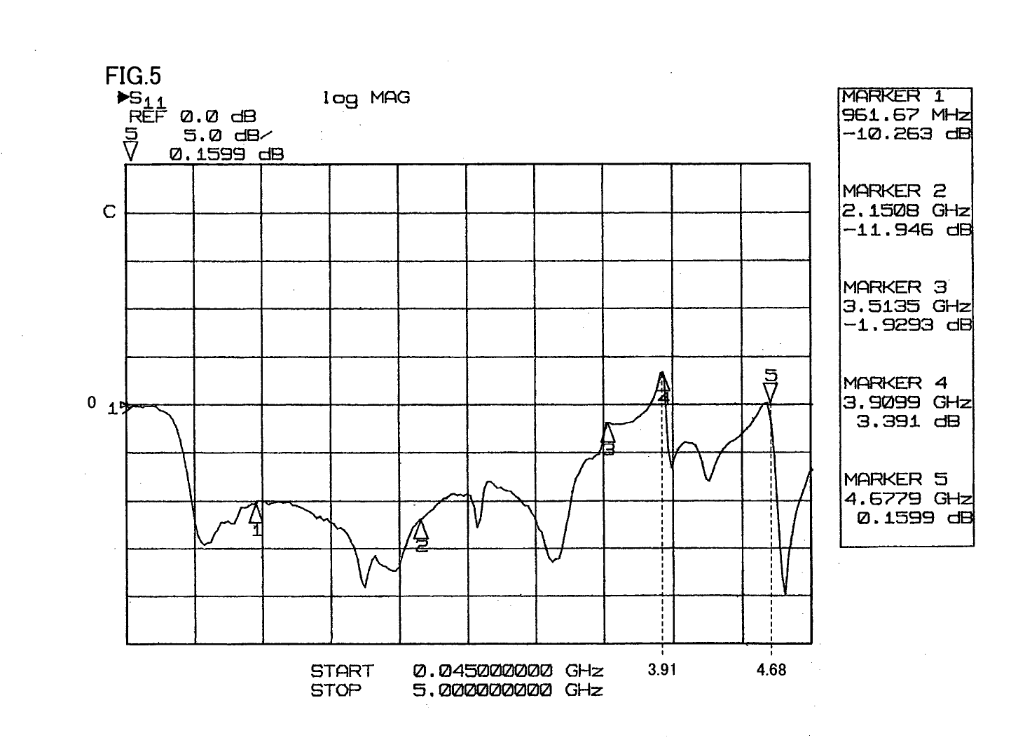

FIG. 5 illustrates characteristics of an output return loss that occurs at output terminal 40 when LNB 5 in FIG. 2 is provided with only bypass capacitor C1 between bypass capacitors C1 and C2.

Output terminal 40 in FIG. 2 must perform the output efficiently in the IF signal band (950 MHz-2150 MHz). Therefore, it is preferable that the return loss is negative and takes a larger absolute value. For signals in the other bands (RF signal band (10.7 GHz-12.75 GHz) for the LNB) and bands (9.75 GHz or 10.6 GHz) of local signals), it is desired that the return loss is small in absolute value for preventing outputting thereof.

Referring to FIG. 5, the abscissa give the frequency, and the ordinate gives the return loss. At the frequencies of 3.91 GHz and 4.68 GHz, the output return loss takes a positive value. This result is likely to occur when bypass capacitor C2 is not employed in the bypass capacitor arrangement shown in FIG. 4. The result in FIG. 5 is obtained when the power supply line (conductor pattern 51 in FIG. 4) connecting output terminal 40 to power supply control circuit 39 via LPF 41 has a portion arranged near the end surface of the board, and an outer side of the portion is not surrounded by the earth pattern. The result exhibits that the oscillation occurs at the two values of frequency in the above state.

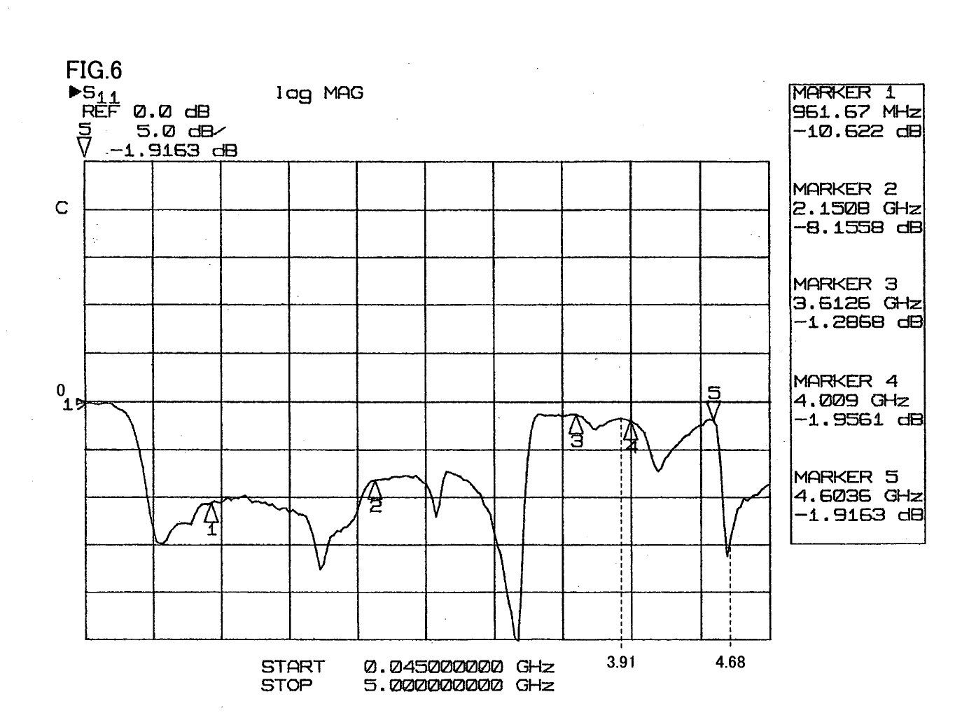

FIG. 6 illustrates characteristics of the output return loss that occurs at output terminal 40 when the LNB in FIG. 2 is provided with bypass capacitors C1 and C2.

Referring to FIG. 6, the output return loss takes negative values at 3.91 GHz and 4.68 GHz. This represents that addition of bypass capacitor C2 prevents the resonance of the board at each of the frequency values of 3.91 GHz and 4.68 GHz.

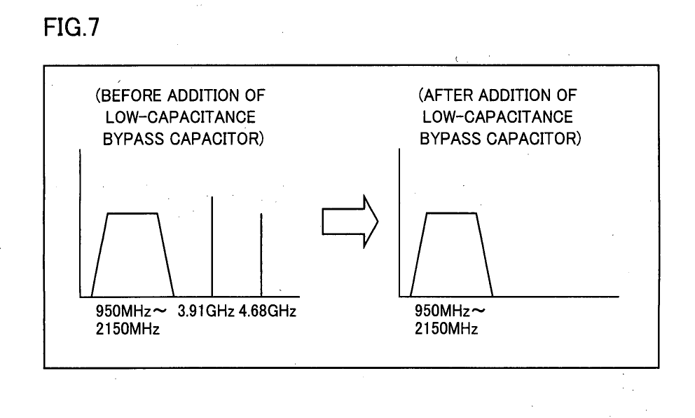

FIG. 7 illustrates changes in signal waveform caused by addition of bypass capacitor C2 in the LNB shown in FIG. 2.

Referring to FIG. 7, the operation of the LNB causes the resonance of the board before bypass capacitor C2 is added. This resonance is reversely transmitted to the amplifier circuit such as HEMTs so that the LNB in FIG. 2 causes resonance at the two resonance frequency values (3.91 GHz and 4.68 GHz). The signal waveform in the frequency range of 950 MHz-2150 MHz is the waveform of the IF signal provided from the LNB during an ordinary operation.

The addition of bypass capacitor C2 to the LNB in FIG. 2 prevents the oscillation of the board at the above frequency values. As illustrated in FIG. 12, the self-resonance frequency of a chip capacitor of a low capacitance of 1 pF-10 pF is present in or near a range of 1.5 GHz-5 GHz. It can be considered that bypass capacitor C2 of 1.5 pF cancels the resonance of the board by the self-resonance.

Two bypass capacitors may be arranged in the power supply line of transmitter 9 in FIG. 1. This can suppress the resonance of transmitter 9 on the circuit board.

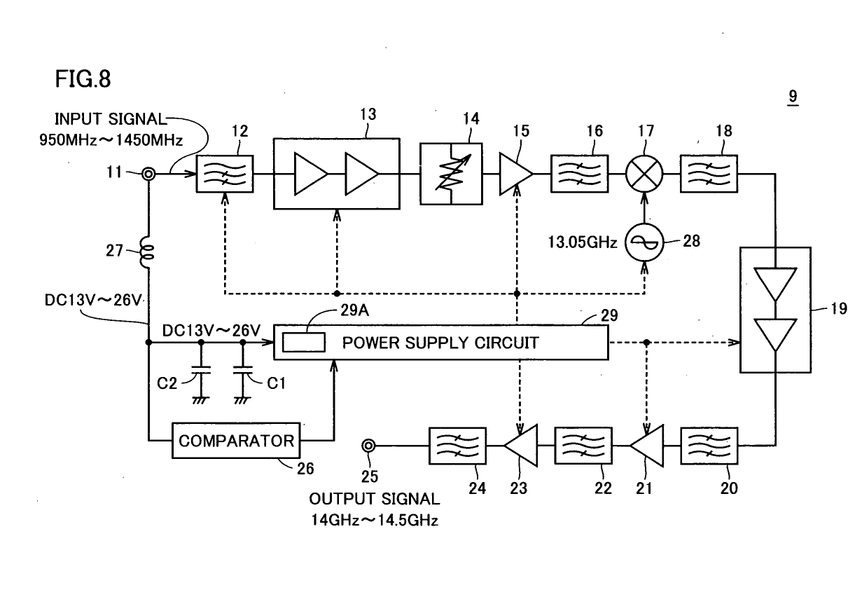

FIG. 8 is a functional block diagram of transmitter 9 in FIG. 1.

Referring to FIG. 8, transmitter 9 includes an input terminal 11, an HPF (High Pass Filter) 12, IF amplifiers 13 and 15, an attenuator circuit 14, BPFs 16, 18, 20, 22 and 24, a mixer 17, a DRO 28, RF amplifiers 19 and 21, a high-power amplifier 23, an output terminal 25, an inductor 27, a comparator 26 and a power supply circuit 29.

Inductor 27 having a function of a low-pass filter passes only a DC bias of 13 V-26 V in a signal received from input terminal 11.

Power supply circuit 29 is supplied with the DC bias via inductor 27, and supplies the power to HPF 12, IF amplifiers 13 and 15, mixer 17, DRO 28, RF amplifiers 19 and 21, and high-power amplifier 23. Power supply circuit 29 corresponds to the “power supply bias circuit” of the invention.

Comparator 26 controls power supply circuit 29 to stop the power supply when the DC bias received via inductor 27 becomes equal to or lower than a predetermined threshold voltage, e.g., of 11 V.

HPF 12 passes only high-frequency components of 950 MHz or more in the signal received from input terminal 11 and having the frequency components in the range of 950 MHz-1450 MHz.

IF amplifier 13 amplifies the signal received from HPF 12. Attenuator circuit 14 adjusts the gain of the signal amplified by IF amplifier 13, and IF amplifier 15 amplifies it again.

BPF 16 passes only the frequency component in the IF band included in the signal received from IF amplifier 15. The signal passed through BPF 16 enters mixer 17. An oscillation signal of a frequency of 13.05 GHz produced by DRO 28 is likewise provided to mixer 17.

Mixer 17 mixes the signal received from BPF 16 with the oscillation signal received from DRO 28, and performs the frequency conversion to provide a signal of a frequency of 14 GHz-14.5 GHz. BPF 18 passes only the frequency components in the RF band included in the signal subjected to the frequency conversion by mixer 17.

RF amplifier 19 amplifies the signal received from BPF 18. BPF 20 passes only the frequency components in the RF band included in the signal amplified by RF amplifier 19. RF amplifiers 21 and BPF 22 operate similarly to RF amplifiers 19 and BPF 20, respectively.

High-power amplifier 23 amplifies the signal received from BPF 22. BPF 24 passes only the frequency components in the RF band included in the signal amplified by power amplifier 23. The signal of the frequency of 14 GHz-14.5 GHz passed through BPF 24 is output from output terminal 25.

Bypass capacitors C1 and C2 are connected in parallel between the power supply line supplying a DC bias from inductor 27 to power supply circuit 29 and the ground. A specific arrangement of bypass capacitors C1 and C2 on the circuit board is substantially the same as that shown in FIG. 3 or 4. Power supply circuit 29 includes a supply control circuit 29A supplying the power according to the DC voltage supplied to the power supply line.

According to the embodiment, as described above, the capacitor having the self-resonance frequency included in the band of the resonance frequency of the circuit board is connected between the power supply line and the earth pattern. This embodiment utilizes such a property of the capacitor that the impedance lowers at the self-resonance frequency, and thereby can suppress the resonance of the board occurring at a certain frequency. Accordingly, the invention can suppress the oscillation and unnecessary radiation that cannot be suppressed by a bypass capacitor of a high capacitance.

The capacitance value of the bypass capacitor and the position thereof on the board in the above embodiment have been described merely by way of example, and it is preferable to determine or select the capacitance value of the bypass capacitor and the position thereof on the board in view of the resonance frequency of the board such that the maximum effect can be achieved.

A manner of approximately calculating the resonance frequency of the board will now be described. As described below, the resonance frequency of the board can be approximately calculated based on the size of the board.

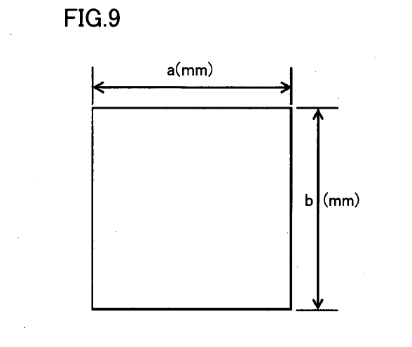

FIG. 9 shows a model of a board used for calculating the resonance frequency.

Referring to FIG. 9, the board has a rectangular form. This rectangle has short and long sides of a and b (mm) in length, respectively. Both the front and rear surfaces of the board are covered with conductors. A resonance frequency fₘₙ of the board can be approximately obtained according to the following formula (1):

$$\begin{matrix}\text{[Formula 1]} & \\ {f}_{mn} = \frac{C}{( 2 π \sqrt{{ɛ}_{r}} )} \sqrt{{( \frac{m π}{a} )}^{2} + {( \frac{n π}{b} )}^{2}} & ( 1 )\end{matrix}$$

where εᵣ represents a dielectric constant of the board, C represents a velocity of light, and each of m and n represents 0 or a positive integer.

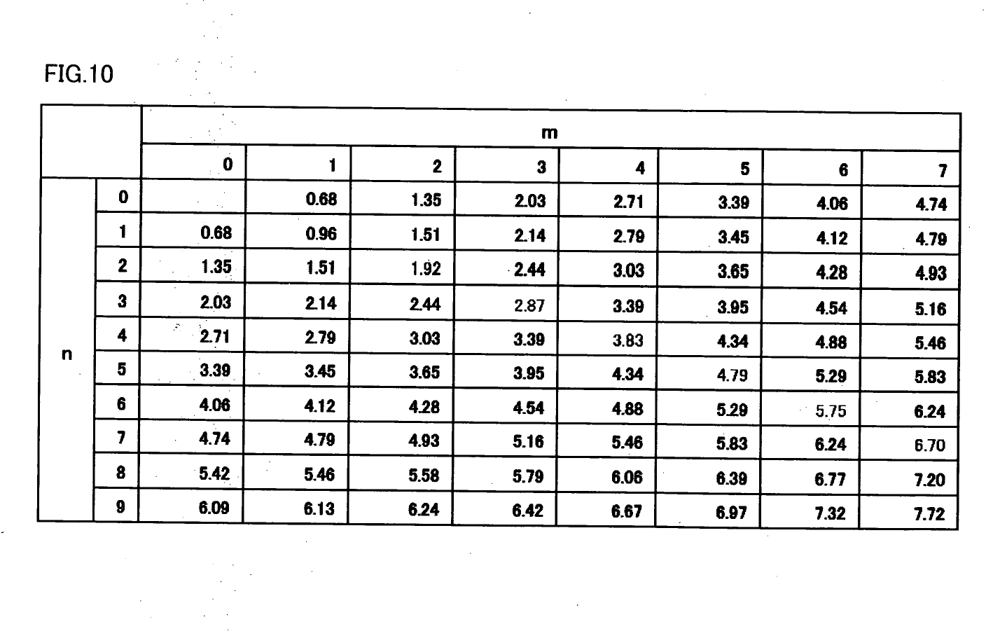

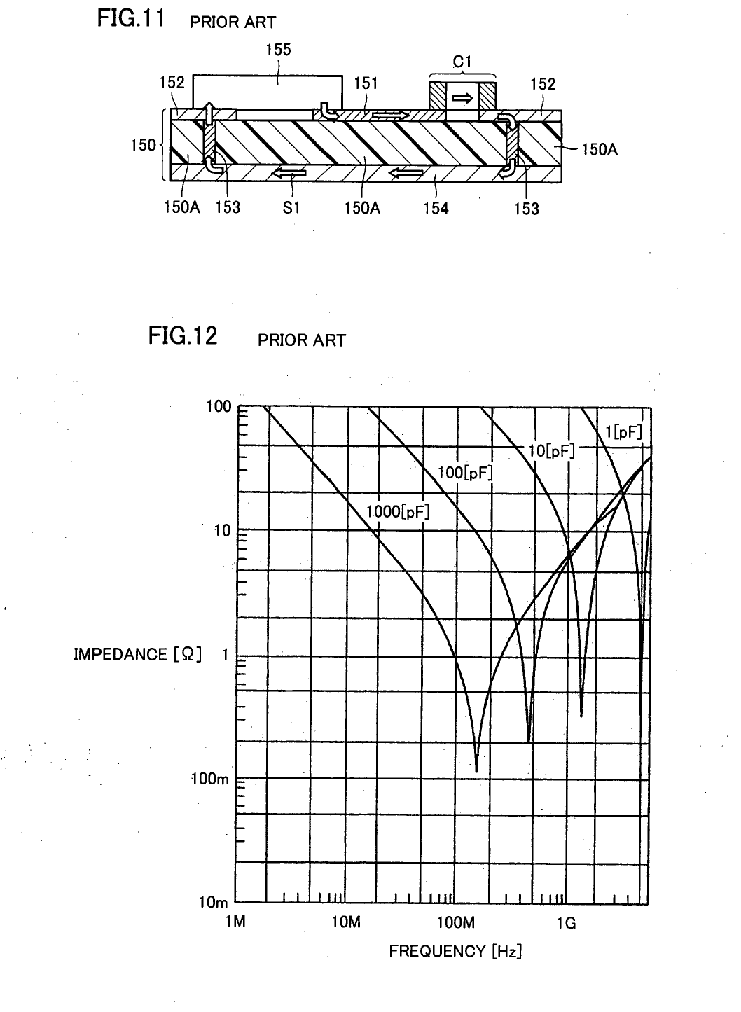

FIG. 10 illustrates, in a table form, the resonance frequency of the board calculated according to the approximate. For calculating the resonance frequency in FIG. 10, it is assumed that the short and long sides of the board have the lengths a and b both equal to 100 mm, and the dielectric constant εᵣ of the board is 4.9.

As shown in FIG. 10, the resonance frequency fₘₙ of the board changes according to the combination of the values of m and n. The resonance frequency in the table is represented in GHz.

As represented by the formula (1), when the size of the board is determined, resonance frequency fₘₙ of the board can be obtained by appropriately combining m and n.

As described above, the size of the board is a basic element for determining the resonance frequency of the board. In practice, however, the position of the signal source and the arrangement of the earth pattern at the periphery of the board are also important elements for determining the resonance frequency of the board. In practice, the these elements are taken into consideration in combination for determining the resonance frequency of the board.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A circuit unit comprising:
a circuit board having a conductor pattern and an earth pattern on a main surface thereof; and
a capacitor connected between said conductor pattern and said earth pattern, wherein
a self-resonance frequency of said capacitor is included in a resonance frequency band of electrical oscillation of said circuit board.

2. The circuit unit according to claim 1, wherein
said capacitor is arranged at an end of said main surface.

3. The circuit unit according to claim 2, wherein
said capacitor is arranged at the end of said main surface such that said conductor pattern is located closer to the end of said main surface than said earth pattern.

4. A power supply bias circuit comprising:
a circuit board having a conductor pattern and an earth pattern on a main surface thereof; and
a first capacitor connected between said conductor pattern and said earth pattern, wherein
a self-resonance frequency of said first capacitor is included in a resonance frequency band of electrical oscillation of said circuit board, and
said power supply bias circuit further comprises a supply control circuit performing supply of power according to a DC voltage applied to said conductor pattern.

5. The power supply bias circuit according to claim 4, further comprising:
a second capacitor connected between said conductor pattern and said earth pattern, wherein
said first capacitor has a smaller capacitance value than said second capacitor.

6. An LNB comprising:
a power supply bias circuit, wherein
said power supply bias circuit includes:
a circuit board having a conductor pattern and an earth pattern on a main surface thereof, and
a capacitor connected between said conductor pattern and said earth pattern;
a self-resonance frequency of said capacitor is included in a resonance frequency band of electrical oscillation of said circuit board; and
said power supply bias circuit further includes a supply control circuit performing supply of power according to a DC voltage applied to said conductor pattern.

7. A transmitter comprising:
a power supply bias circuit, wherein
said power supply bias circuit includes:
a circuit board having a conductor pattern and an earth pattern on a main surface thereof, and
a capacitor connected between said conductor pattern and said earth pattern;
a self-resonance frequency of said capacitor is included in a resonance frequency band of electrical oscillation of said circuit board; and
said power supply bias circuit further includes a supply control circuit performing supply of power according to a DC voltage applied to said conductor pattern.
